(19) United States
(12) Patent Application Publication
(10) Pub. No.: US 2011/0267211 A1
(43) Pub. Date: Nov. 3, 2011

(54) ANALOG-DIGITAL CONVERTER AND OPERATING METHOD THEREOF

(75) Inventors: Takashi OSHIMA, Moriya (JP); Tomomi TAKAHASHI, Musashino (JP)

(73) Assignee: RENESAS ELECTRONICS CORPORATION

(21) Appl. No.: 13/095,693

(22) Filed: Apr. 27, 2011

(30) Foreign Application Priority Data
Apr. 28, 2010 (JP) 2010-102980

(51) Int. Cl. H03M 1/06

(52) U.S. Cl. 341/118

(57) ABSTRACT

In this invention, the accuracy between an input analog voltage and a digital output signal can be enhanced. A background digital correction type A/D converter includes a reference A/D conversion unit, a main A/D conversion unit, and a digital corrector. The main A/D conversion unit executes an A/D converting operation at a high speed, whereas the reference A/D conversion unit executes an A/D converting operation with high resolution, respectively. Each of main digital output signals of the main A/D conversion unit and a reference digital output signal of the reference A/D conversion unit are supplied to one input terminal of the digital corrector and the other input terminal thereof respectively. The digital corrector outputs a correction-processing digital output signal. The reference A/D conversion unit includes a ΣΔ A/D converter and a Nyquist filter. The Nyquist filter suppresses a high-frequency quantization error of the ΣΔ analog-digital converter.

### CROSS-REFERENCE TO RELATED APPLICATIONS

The present application claims priority from Japanese patent application JP 2010-102980 filed on Apr. 28, 2010, the content of which is hereby incorporated by reference into this application.

### BACKGROUND

The present invention relates to an analog-digital converter and an operating method thereof, and particularly to a technology effective in improving the accuracy between an input analog voltage of a ΣΔ type analog-digital converter and a digital output signal thereof when the ΣΔ type analog-digital converter is used as a reference analog-digital conversion unit of a background digital correction-type analog-digital converter.

Next-generation medical devices, industrial inspection devices, wireless communication systems, etc. are respectively required to have an analog-digital converter which makes an extremely high resolution of greater than or equal to 11 bits or so, and a high sample rate of greater than or equal 100 mega samples per second (100 Ms/s).

As one example of a hithertofore-used fast and high-resolution analog-digital converter, a background digital correction type analog-digital converter using a reference analog-digital conversion unit has been described in non-patent documents 1, 2 and 3 and a patent document 1 to be described below, etc.

The background digital correction type analog-digital converter includes a high-speed operable main analog-digital converter, a low-speed operable sub reference analog-digital converter, a digital background error correction unit, and a digital value reproduction unit. A main digital signal of the main analog-digital converter is supplied to one input terminal of the digital value reproduction unit, and a subdigital signal of the sub reference analog-digital converter is supplied to one input terminal of an error subtractor of the digital background error correction unit. A reproduced output signal outputted from the digital value reproduction unit is supplied to the other input terminal of the error subtractor. Using the result of the signal outputted from the error subtractor, the digital background error correction unit updates a coefficient of the digital value reproduction unit in accordance with an LMS (Least Mean Square) algorithm and supplies the updated coefficient to the other input terminal of the digital value reproduction unit.

On the other hand, a ΣΔ analog-digital converter capable of linear conversion between an analog signal and a digital signal using simple analog hardware components has been described in a non-patent document 4 to be described below. Combining the ΣΔ analog-digital converter and a decimation filter makes it possible to obtain a satisfactory signal resolution. A high-frequency single bit stream of the output of the ΣΔ analog-digital converter can be converted to a pulse code modulated (PCM) signal by the decimation filter.

Further, a pulse shaping filter called a Nyquist filter has been described in a patent document 2 to be described below as each of transmission and reception filters for reducing Inter-symbol Interference (ISI) in a digital communication system. At an impulse response of the Nyquist filter, the waveform amplitude becomes a maximum value 1 with a symbol timing at time zero, whereas the waveform amplitude becomes zero with another symbol timing separated by an integral multiple of one period of a symbol clock frequency. When a roll-off factor α=0 at a frequency response of the Nyquist filter, the Nyquist filter serves as a “brick wall” filter in which the amplitude steeply changes with the characteristic frequency thereof as the boundary. When the roll-off factor α=0.5 or α=1.0, it serves as a Nyquist filter in which the amplitude gently changes with the characteristic frequency thereof as the boundary.

### Patent Document 1:

Japanese Unexamined Patent Publication No. 2009

### Patent Document 2:

U.S. Pat. No. 6,628,728 B1, Specification

### Non-Patent Document 1:

Takashi Oshima et al, “Fast Digital Background Calibration for Pipelined ADCs”, IEICE Technical Report VLD2006-138, ICD2006-229, PP. 115-120 March 2007

### Non-Patent Document 2:

Wenbo Liu et al, “An Equalization-Based Adaptive Digital Background Calibration Technique for Successive Approximation Analog-to-Digital Converter”, 7th International Conference on ASIC, 2007, PP. 289-292. 22-25 Oct. 2007

### Non-Patent Document 3:

Takashi Oshima et al, “Fast Nonlinear Deterministic Calibration of Pipelined A/D converters”, 2008 IEEE Midwest Symposium on Circuits and Systems, PP. 914-917

### Non-Patent Document 4:

E. Pfann et al, “Oversampled sigma-delta LMS adaptive FIR filters”, IEE proceedings-Vison, Image and Signal Processing, Vol. 147, No. 5, PP. 385-392. October 2000

### SUMMARY

The present inventors were involved in the study and development of an analog-digital converter which enables an extremely high resolution of greater than or equal to 11 bits or so and a high sample rate of 100 Ms/s or more to be compatible, prior to the present invention.

FIG. 1 is a diagram showing a configuration of a background correction type analog-digital converter discussed by the present inventors prior to the present invention, which is used as an analog-digital converter that enables high resolution and a high sample rate to be compatible.

As shown in FIG. 1, the background digital correction type analog-digital converter is comprised of a reference analog-digital conversion unit 10, a main analog-digital conversion unit 13 and a digital corrector 18. The main analog-digital conversion unit 13 executes a fast A/D converting operation with low accuracy to reduce power consumption. On the other hand, the reference analog-digital conversion unit 10 executes a high-resolution A/D converting operation at a low speed in the background, and the digital corrector 18 executes a digital correction in the background. Accordingly, the background digital correction type analog-digital converter shown in FIG. 1 enables high resolution and a high sample rate to be compatible with relatively low power consumption.

That is, since an input terminal of the reference analog-digital conversion unit 10 and an input terminal of the main analog-digital conversion unit 13 are coupled to an analog input terminal IN, the two analog-digital conversion units respectively perform a sampling operation and an analog-digital converting operation on substantially the same analog input voltage supplied to the analog input terminal IN.

On the other hand, since the main analog-digital conversion unit 13 is required to operate at high speed at a high sample rate needed therefor, the main analog-digital conversion unit 13 makes use of the pipelined analog-digital converter described in each of the above non-patent documents 1 and 2 and the like, or the successive approximation analog-digital converter described in the above non-patent document 2 or the like.

In the background digital correction type analog-digital converter shown in FIG. 1, the main analog-digital conversion unit 13 is configured by the successive approximation analog-digital converter as an example. For this reason, the main analog-digital conversion unit 13 includes a sample hold circuit 14, a comparator 15, a controller 16 and a local digital-analog converter 17. That is, an input terminal of the sample hold circuit 14 is coupled to the analog input terminal IN, and an output terminal thereof is coupled to a non-inversion input terminal + of the comparator 15. An output terminal of the comparator 15 is coupled to an input terminal of the controller 16. Multibit digital output signals of the controller 16 are coupled to multibit digital input terminals of the local digital-analog converter 17. A local analog output signal of the local digital-analog converter 17 is supplied to an inversion input terminal − of the comparator 15. Such multibit digital output signals that the local analog output signal of the local digital-analog converter 17 supplied to the inversion input terminal of the comparator 15 follows the analog input signal placed in hold state, which is supplied from the analog input terminal IN to the non-inversion input terminal of the comparator 15 via the sample hold circuit 14 during a hold period subsequent to a sample period are generated from the controller 16. For this reason, the main analog-digital conversion unit 13 is operated as the successive approximation analog-digital converter.

Since the multibit digital output signals D₁ through D_{N} form the controller 16 of the main analog-digital conversion unit 13 are supplied to the digital corrector 18, the process of correcting the multibit digital output signals D₁ through D_{N} by the digital corrector 18 is executed, after which the so correction-processed output signal is outputted to the outside as the entire digital converted output signal of the background digital correction type analog-digital converter shown in FIG. 1. That is, since the multibit digital output signals D₁ through D_{N} of the main analog-digital conversion unit 13 are supplied to a digital output generator 113 lying inside the digital corrector 18, the operation of multiplying the multibit digital output signal D₁ through D_{N} by correction factors Wi respectively inside the digital corrector 18 is executed, and an offset dc component W_{OFS} is further added to the result of multiplication. Owing to the above multiplication operation, variations in device values used in the internal local digital-analog converter 17, and like can be compensated where the main analog-digital conversion unit 13 is of the successive approximation analog-digital converter as shown in FIG. 1. On the other hand, when the main analog-digital conversion unit 13 is configured by the pipelined analog-digital converter, a low gain property and a non-linear characteristic or the like of each operational amplifier provided thereinside, and variations in sampling capacitance values, etc. can be compensated. Further, a DC offset of the main analog-digital conversion unit 13 can be compensated by the correction based on the above offset dc component W_{OFS}.

The search for the correction factors Wi by the digital corrector 18 is executed in accordance with, for example, an LMS (Least Mean Square) algorithm in the below-described manner. An error in conversion between the output signal of the digital output generator 113 used as the output signal of the digital corrector 18, and the reference analog-digital converted output signal from the reference analog-digital conversion unit 10 is calculated by a subtractor 19. A negative feedback loop for updating the value of the current correction factor Wi is formed based on the result of the above calculation. Specifically, for the search for the corresponding correction factor Wi, the error in conversion corresponding to the output of the subtractor 19 and the corresponding digital output signal Di from the main analog-digital conversion unit 13 are multiplied by each other by a multiplier 110. Further, in order to achieve negative feedback control having desired loop gain, the result of multiplication is multiplied by a negative fixed value −μ by a constant multiplier 111. The corresponding correction factor Wi can be obtained from the output of an integrator 112 by integration of the multiplied output signal of the constant multiplier 111 by the integrator 112. With the formation of the above negative feedback control loop, the value of the correction factor Wi is automatically updated and controlled until the output signal of the digital corrector 18 coincides with the reference analog-digital converted output signal from the reference analog-digital conversion unit 10 with high accuracy. Incidentally, for the parallel search for a plurality of correction factors Wi (where i=1 to N), the digital corrector 18 is provided, in plural form, with the above subtractor 19, multiplier 110, constant multiplier 111 and integrator 112.

On the other hand, since the reference analog-digital conversion unit 10 needs to perform the high-accuracy/high resolution A/D converting operation as described above, a low-speed operation is required for low power consumption. As the reference analog-digital converter 12 included in the reference analog-digital conversion unit 10, the use of the pipelined analog-digital converter or the successive approximation analog-digital converter used in the main analog-digital conversion unit 10 was studied. However, the problem that the circuit scale in the case of the configuration thereof in a semiconductor integrated circuit becomes larger, thereby increasing power consumption was revealed by the study of the present inventors. The use of the ΣΔ type analog-digital converter described in the non-patent document 4 as the reference analog-digital converter 12 included in the reference analog-digital conversion unit 10 was studied. The reference analog-digital converter 12 using the ΣΔ type analog-digital converter is reduced in circuit scale and enables a reduction in power consumption.

A new problem was however revealed by the study of the present inventors by using the ΣΔ type analog-digital converter as the reference analog-digital converter 12 included in the reference analog-digital conversion unit 10 executing the high accuracy/high resolution A/D converting operation.

That is, it means the effects of high-frequency quantization noise generated by a quantizer provided inside the ΣΔ type analog-digital converter. FIG. 2 is a diagram showing the manner of high-frequency quantization noise generated by a ΣΔ type analog-digital converter of a reference analog-digital converter 12 in the background digital correction type analog-digital converter discussed by the present inventors prior to the present invention shown in FIG. 1.

As well known, the ΣΔ type analog-digital converter (sigma delta type analog-digital converter) performs an internal operation on an internal operation clock (i.e., oversampling operation clock) about 10 to several 100 times faster than the required conversion rate or input signal band to thereby obtain high resolution even if a quantizer having a relative coarse resolution of 1 to 4 bits or so is used. Thus, the ΣΔ type analog-digital converter performs noise shaping for diffusing a large quantization error generated by the internal relatively coarse quantizer into a high-frequency region as shown in FIG. 2 to thereby drastically reduce quantization error components in a signal band. The above noise shaping is achieved by executing a differential operation and an integral operation responsive to an oversampling operation clock by an analog circuit of a ΣΔ modulator. Since a high signal vs quantization error ratio can be recovered at a filter output by band-limiting the quantization digital output of the ΣΔ modulator to a signal band by a digital low-pass filter coupled to its output, high resolution can be obtained. A digital output signal at this time slightly changes in amplitude and phase by the above digital low-pass filter. In the normal use of the ΣΔ type analog-digital converter, however, the high accuracy of coincidence between the analog input signal and the digital output signal is not required but the high signal vs quantization error ratio is seriously considered, thereby causing no problem. That is, since the digital output signal responsive to the high-frequency component of the analog input signal is attenuated by band limitation by the narrow-band digital low-pass filter, the accuracy of coincidence between the analog input signal and the digital output signal is reduced.

When, however, the ΣΔ type analog-digital converter is used as the reference analog-digital conversion unit for the above digital correction, there is a need to allow the analog signal and the digital output signal at the reference analog-digital conversion unit to coincide with each other highly accurately. It was therefore revealed by the study of the present inventors prior to the present invention that the inconsistency between the analog input signal and the digital output signal came to surface as a large problem. In order to solve the problem, a band limitation by a wideband digital low-pass filter was also discussed by the present inventors prior to the present invention. However, another problem that the digital output signal responsive to each high-frequency quantization error component, of the quantizer is outputted from the wideband digital low-pass filter was also revealed by the study of the present inventors prior to the present invention.

When the ΣΔ type analog-digital converter 12 is used as the reference analog-digital conversion unit 10 as shown in FIG. 1 in terms of this background, a pre-signal process for holding an input signal waveform in step form by coupling a low-speed sample hold circuit 11 to the input terminal of the ΣΔ type analog-digital converter 12 was discussed by the present inventors prior to the present invention. That is, since the low-speed sample hold circuit 11 converts the amplitude voltage of the analog input signal of the analog input terminal IN to an output signal detected and held with sampling timing, a high-frequency component of the analog input signal at the analog input terminal IN is not contained in the output signal of the low-speed sample hold circuit 11.

Thus, the high-frequency component of the analog input signal is not contained in the input of the ΣΔ type analog-digital converter 12 by coupling the low-speed sample hold circuit 11 to the input of the ΣΔ type analog-digital converter 12 used as for the reference analog-digital conversion unit 10 as shown in FIG. 1. Therefore, the effective accuracy of coincidence between the analog input signal and the digital output signal at the reference analog-digital conversion unit 10 is improved by enabling a process of each side lobe to be described later.

Actually, in the background digital correction type analog-digital converter shown in FIG. 1, a signal frequency supplied to the reference analog-digital conversion unit 10 needs to be assumed up to the value of a Nyquist frequency (i.e., ½ of a fast sampling clock frequency of main analog-digital conversion unit 13) of the main analog-digital conversion unit 13. Therefore, the problem about the accuracy of coincidence between the analog input signal and the digital output signal at the reference analog-digital conversion unit 10 arises under the normal use conditions of the background digital correction type analog-digital converter. Thus, when the ΣΔ type analog-digital converter is used as the reference analog-digital conversion unit 10 at the background digital correction type analog-digital converter, there is a need to perform the pre-signal process by the low-speed sample hold circuit 11. Further, when the low-speed sample hold circuit 11 executes a holding operation every time interval T, the conversion rate of the reference analog-digital conversion unit 10 becomes 1/T. Actually, however, when the step-shaped waveform signal held by the low-speed sample hold circuit 11 is expressed in the frequency component at this time, each side lobe lying in a high-frequency region with n/T as the center is contained even other than a main lobe of a frequency band 0 to 1/(2T) as shown in FIG. 2. Incidentally, n is an integer greater than or equal to 1.

Thus, when a priority is placed on the high accuracy of coincidence between the analog input and the digital output necessary as for the reference analog-digital conversion unit 10, there is a need to adopt such a wideband digital low-pass filter as shown in FIG. 2 in such a manner that each side lobe in the high-frequency region can be held in the band. As a result, a lot of quantization errors noise-shaped and diffused into the high-frequency region by the ΣΔ modulator are contained in the output of the digital low-pass filter. For this reason, a problem that since the signal vs quantization error ratio (i.e., effective resolution) is reduced, the above reference analog-digital conversion unit is not able to sufficiently function as the reference analog-digital conversion unit 10 of the background digital correction type analog-digital converter was revealed by the study of the present inventors prior to the present invention.

The present invention has been made as the above result of the study by the present inventors prior to the present invention.

It is therefore an object of the present invention to improve the accuracy between an input analog voltage and a digital output signal of a ΣΔ type analog-digital converter when the ΣΔ type analog-digital converter is used as a reference analog-digital conversion unit of a background digital correction analog-digital converter.

The above and other objects and novel features of the present invention will be apparent from the description of the specification and the accompanying drawings.

A typical one of the inventive aspects of the invention disclosed in this application will be briefly described as follows:

A typical embodiment of the present invention is an A/D converter configured as a background digital correction type A/D converter.

The background digital correction type A/D converter is equipped with a reference A/D conversion unit (10), a main A/D conversion unit (13), and a digital corrector (18).

An input terminal of the reference A/D conversion unit (10) and an input terminal of the main A/D conversion unit (13) are coupled to an analog input terminal (IN) of the A/D converter to thereby allow the reference A/D conversion unit (10) and the main A/D conversion unit (13) to perform an A/D converting operation on substantially the same analog input voltage supplied to the analog input terminal (IN).

The main A/D conversion unit (13) executes an A/D converting operation at a speed faster than that of the reference A/D conversion unit (10), whereas the reference A/D conversion unit (10) executes an A/D converting operation with a resolution higher than that of the main A/D conversion unit (13).

Each of main digital output signals (D₁ through D_{N}) generated by the A/D converting operation of the main A/D conversion unit (13) is supplied to one input terminal of the digital corrector (18), and a reference digital output signal generated by the A/D converting operation of the reference A/D conversion unit (10) is supplied to the other input terminal of the digital corrector (18).

The digital corrector (18) outputs a correction-processing digital output signal generated in response to each of the main digital output signals (D₁ through D_{N}) and the reference digital output signal as a digital conversion output signal of the A/D converter.

The reference A/D conversion unit (10) includes a ΣΔ A/D converter (22) capable of responding to the analog input voltage supplied to the analog input terminal (IN), and a Nyquist filter (23) which is capable of responding to an output signal of the ΣΔ A/D converter (22) and supplying the output signal to the other input terminal of the digital corrector (18) as the reference digital output signal (refer to FIG. 3).

An advantageous effect obtained by a typical one of the invention disclosed in the present application will be briefly explained as follows:

According to the present invention, the accuracy between an input analog voltage and a digital output signal of a ΣΔ type analog-digital converter can be improved when the ΣΔ type analog-digital converter is used as a reference analog-digital conversion unit of a background digital correction type analog-digital converter.

### BRIEF DESCRIPTION OF THE DRAWINGS

FIG. 1 is a diagram showing a configuration of a background correction type analog-digital converter discussed by the present inventors prior to the present invention, which is used as an analog-digital converter that enables high resolution and a high sample rate to be compatible;

FIG. 2 is a diagram showing the manner of high-frequency quantization noise generated by a ΣΔ type analog-digital converter of a reference analog-digital converter 12 of the background digital correction type analog-digital converter discussed by the present inventors prior to the present invention shown in FIG. 1;

FIG. 3 is a diagram illustrating a configuration of a background digital correction type analog-digital converter used as an analog-digital converter according to a first embodiment of the present invention, which enables high resolution and a high sample rate to be compatible;

FIG. 4 is a diagram for further describing the operations of an impulse hold circuit 21, a ΣΔ analog-digital converter 22, and a Nyquist filter 23 included in a reference analog-digital conversion unit 10 of the background digital correction type analog-digital converter according to the first embodiment of the present invention shown in FIG. 3;

FIG. 5 is a diagram showing a transfer characteristic of the Nyquist filter 23 shown in FIG. 4, a signal of a main lobe of a frequency band 0 to 1/2T, which is outputted from the ΣΔ analog-digital converter 22 shown in FIG. 4, a signal of each side lobe higher than the main lobe, and a quantization error;

FIG. 6 is a diagram illustrating a frequency characteristic for band limiting of the Nyquist filter 23 included in the reference analog-digital conversion unit 10 of the background digital correction type analog-digital converter according to the first embodiment of the present invention shown in FIG. 3;

FIG. 7 is a diagram showing an impulse response of the Nyquist filter 23 included in the reference analog-digital conversion unit 10 of the background digital correction type analog-digital converter according to the first embodiment of the present invention shown in FIG. 3;

FIG. 8 is a diagram illustrating a configuration of a background digital correction type analog-digital converter according to a second embodiment of the present invention, which is used as an analog-digital converter that enables high resolution and a high sample rate to be compatible;

FIG. 9 is a diagram for further describing the operations of a rectangular hold circuit 24, a ΣΔ analog-digital converter 22, a Nyquist filter 23 and an equivalent filter 25 included in a reference analog-digital conversion unit 10 of the background digital correction type analog-digital converter according to the second embodiment of the present invention shown in FIG. 8;

FIG. 10 is a diagram showing a configuration of a background digital correction type analog-digital converter according to a third embodiment of the present invention, which is used as an analog-digital converter that enables high resolution and a high sample rate to be compatible;

FIG. 11 is a diagram for further describing the operations of an M-period hold circuit 26, a ΣΔ analog-digital converter 22, a Nyquist filter 23 and an equivalent filter 25 included in a reference analog-digital conversion unit 10 of the background digital correction type analog-digital converter according to the third embodiment of the present invention shown in FIG. 10;

FIG. 12 is a diagram showing a configuration of a background digital correction type analog-digital converter according to a fourth embodiment of the present invention, which is used as an analog-digital converter that enables high resolution and a high sample rate to be compatible;

FIG. 13 is a diagram showing a configuration of each of a thinning filter 27, a Nyquist filter 23 and an equivalent filter 25 included in a reference analog-digital conversion unit 10 shown in FIG. 12; and

FIG. 14 is a diagram illustrating a configuration of a pipelined analog-digital converter usable as the main analog-digital conversion unit 13 of each of the background digital correction type analog-digital converters according to all of the first through fourth embodiments of the present invention.

### DETAILED DESCRIPTION

### 1. Summary of the Embodiments

A summary of typical embodiments of the invention disclosed in the present application will first be explained. Reference numerals of the accompanying drawings referred to with parentheses in the description of the summary of the typical embodiments only illustrate elements included in the concept of components to which the reference numerals are given.

[1] A typical embodiment of the present invention is an analog-digital converter configured as a background digital correction type analog-digital converter.

The background digital correction type analog-digital converter includes a reference analog-digital conversion unit (10), a main analog-digital conversion unit (13), and a digital corrector (18).

An input terminal of the reference analog-digital conversion unit (10) and an input terminal of the main analog-digital conversion unit (13) are coupled to an analog input terminal (IN) of the analog-digital converter, whereby the reference analog-digital conversion unit (10) and the main analog-digital conversion unit (13) perform an analog-digital converting operation on substantially the same analog input voltage supplied to the analog input terminal (IN).

The main analog-digital conversion unit (13) is capable of executing an analog-digital converting operation at a speed faster than that of the reference analog-digital conversion unit (10). On the other hand, the reference analog-digital conversion unit (10) is capable of executing an analog-digital converting operation with a resolution higher than that of the main analog-digital conversion unit (13).

Each of main digital output signals (D₁ through D_{N}) generated by the analog-digital converting operation of the main analog-digital conversion unit (13) is capable of being supplied to one input terminal of the digital corrector (18). A reference digital output signal generated by the analog-digital converting operation of the reference analog-digital conversion unit (10) is capable of being supplied to the other input terminal of the digital corrector (18).

The digital corrector (18) is capable of outputting a correction-processing digital output signal generated in response to each of the main digital output signals (D₁ through D_{N}) and the reference digital output signal as a digital conversion output signal of the analog-digital converter.

The reference analog-digital conversion unit (10) includes a ΣΔ analog-digital converter (22) capable of responding to the analog input voltage supplied to the analog input terminal (IN), and a Nyquist filter (23) which is capable of responding to an output signal of the ΣΔ analog-digital converter (22) and supplying the output signal to the other input terminal of the digital corrector (18) as the reference digital output signal (refer to FIG. 3).

According to the present embodiment, when a ΣΔ type analog-digital converter is used as a reference analog-digital conversion unit of a background digital correction type analog-digital converter, the Nyquist filter (23) is operated so as to suppress a quantization error in high frequency of the ΣΔ analog-digital converter (22). As a result, it is possible to enhance accuracy between an input analog voltage and a digital output signal of the ΣΔ type analog-digital converter.

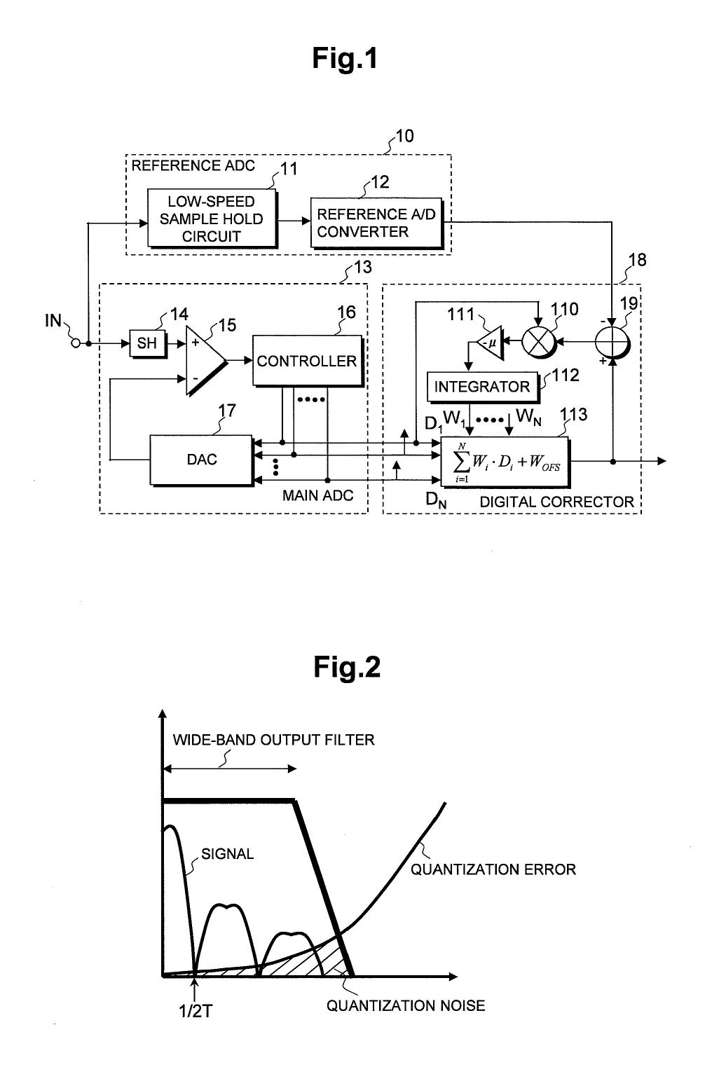

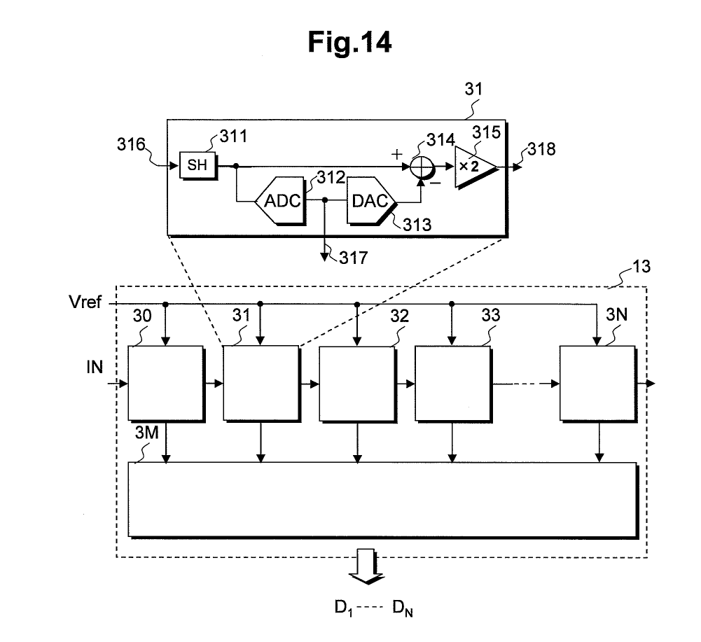

According to a preferred embodiment, the main analog-digital conversion unit (13) is configured by either a successive approximation type analog-digital converter or a pipelined analog-digital converter (refer to FIGS. 1 and 14).

According to another preferred embodiment, the reference analog-digital conversion unit (10) further includes a signal hold circuit (21, 24, 26) capable of generating a pulse signal by sampling the analog input voltage supplied to the analog input terminal (IN) for every predetermined symbol period (T) and supplying the same to an input terminal of the ΣΔ analog-digital converter (22) (refer to FIGS. 3, 8, 10 and 12).

According to a more preferred embodiment, the Nyquist filter (23) has an impulse response set in such a manner that an amplitude waveform assumes a predetermined magnitude with a symbol timing at a zero time of the predetermined symbol period T and the amplitude waveform becomes substantially zero with another symbol timing equal to an integral multiple of the predetermined symbol period (T) (refer to FIG. 7).

According to another more preferred embodiment, the signal hold circuit is an impulse hold circuit (21) which samples the analog input voltage for every predetermined symbol period (T) to thereby generate an impulse signal having a pulse width (1/f_{CLK}) shorter than the predetermined symbol period (T) (refer to FIG. 3).

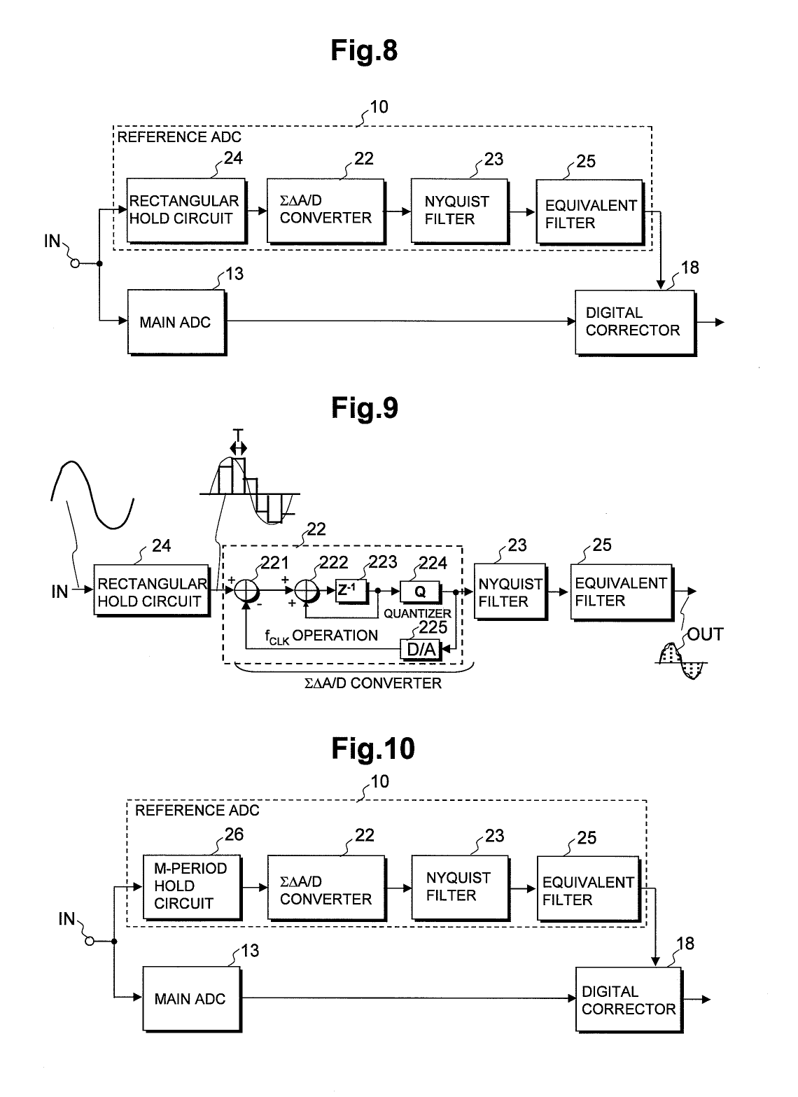

According to a further more preferred embodiment, the signal hold circuit is a rectangular hold circuit (24) which samples the analog input voltage for every predetermined symbol period (T) to thereby generate a rectangular pulse signal having a pulse width (T) substantially equal to the predetermined symbol period (T) (refer to FIG. 8).

According to a concrete embodiment, the reference analog-digital conversion unit (10) further includes an equivalent filter (25) coupled between an output terminal of the Nyquist filter (23) and the other input terminal of the digital corrector (18) (refer to FIG. 8).

According to a yet another more preferred embodiment, the signal hold circuit is a period hold circuit (26) which samples the analog input voltage for every predetermined symbol period (T) to thereby generate a hold pulse signal having a hold period (M) shorter than the predetermined symbol period (T) (refer to FIGS. 10 and 12).

According to another concrete embodiment, the reference analog-digital conversion unit (10) further includes an equivalent filter (25) coupled between an output terminal of the Nyquist filter (23) and the other input terminal of the digital corrector (18) (refer to FIG. 12).

According to a further concrete embodiment, the reference analog-digital conversion unit (10) further includes a thinning filter (25) coupled between an output terminal of the ΣΔ analog-digital converter (22) and an input terminal of the Nyquist filter (23) (refer to FIG. 12).

[2] A typical embodiment according to another aspect of the present invention is an operating method of an analog-digital converter configured as a background digital correction type analog-digital converter.

The background digital correction type analog-digital converter includes a reference analog-digital conversion unit (10), a main analog-digital conversion unit (13), and a digital corrector (18).

An input terminal of the reference analog-digital conversion unit (10) and an input terminal of the main analog-digital conversion unit (13) are coupled to an analog input terminal (IN) of the analog-digital converter, whereby the reference analog-digital conversion unit (10) and the main analog-digital conversion unit (13) perform an analog-digital converting operation on substantially the same analog input voltage supplied to the analog input terminal (IN).

The main analog-digital conversion unit (13) is capable of executing an analog-digital converting operation at a speed faster than that of the reference analog-digital conversion unit (10). On the other hand, the reference analog-digital conversion unit (10) is capable of executing an analog-digital converting operation with a resolution higher than that of the main analog-digital conversion unit (13).

Each of main digital output signals (D₁ through D_{N}) generated by the analog-digital converting operation of the main analog-digital conversion unit (13) are capable of being supplied to one input terminal of the digital corrector (18). A reference digital output signal generated by the analog-digital converting operation of the reference analog-digital conversion unit (10) is capable of being supplied to the other input terminal of the digital corrector (18).

The digital corrector (18) is capable of outputting a correction-processing digital output signal generated in response to each of the main digital output signals (D₁ through D_{N}) and the reference digital output signal as a digital conversion output signal of the analog-digital converter.

The reference analog-digital conversion unit (10) includes a ΣΔ analog-digital converter (22) capable of responding to the analog input voltage supplied to the analog input terminal (IN), and a Nyquist filter (23) which is capable of responding to an output signal of the ΣΔ analog-digital converter (22) and supplying the output signal to the other input terminal of the digital corrector (18) as the reference digital output signal (refer to FIG. 3).

The Nyquist filter (23) is operated so as to suppress a quantization error in high frequency of the ΣΔ analog-digital converter (22) (refer to FIG. 5).

According to the present embodiment, when a ΣΔ type analog-digital converter is used as a reference analog-digital conversion unit of a background digital correction type analog-digital converter, the accuracy between an input analog voltage and a digital output signal of the ΣΔ type analog-digital converter can be enhanced.

### 2. Further Detailed Description of the Embodiments

Embodiments will next be explained in more detail. Incidentally, in all drawings for describing the best modes for implementing the invention, components having the same functions as in the above drawings are respectively identified by like reference numerals, and their repetitive explanations will therefore be omitted.

### First Embodiment

### Configuration of Analog-Digital Converter of First Embodiment

FIG. 3 is a diagram showing a configuration of a background digital correction type analog-digital converter used as an analog-digital converter according to a first embodiment of the present invention, which enables high resolution and a high sample rate to be compatible.

The background digital correction type analog-digital converter according to the first embodiment of the present invention shown in FIG. 3 is comprised of a reference analog-digital conversion unit 10, a main analog-digital conversion unit 13, and a digital corrector 18 in a manner similar to the background correction type analog-digital converter discussed by the present inventors prior to the present invention shown in FIG. 1.

The operation of the background digital correction type analog-digital converter according to the first embodiment of the present invention, which is comprised of the reference analog-digital conversion unit 10, the main analog-digital conversion unit 13 and the digital corrector 18 shown in FIG. 3 is exactly similar to FIG. 1, and the description of its operation will therefore be omitted.

### <<Successive Approximation Type A/D Converter Used as the Main Analog-Digital Conversion Unit>>

In a manner similar to FIG. 1, although not illustrated in FIG. 3, the main analog-digital conversion unit 13 includes a sample hold circuit 14, a comparator 15, a controller 16 and a local digital-analog converter 17 to configure the successive approximation type analog-digital converter. The controller 16 includes a control register therein. The control register generates multibit digital output signals D₁ through D_{N} of the controller 16. Digital values (the contents of control register) of the multibit digital output signals D₁ through D_{N} of the control register provided inside the controller 16 are updated by a search algorithm called “binary search”, for example.

At a first step for A/D conversion of the successive approximation type analog-digital converter, the contents of the control register is set to a digital value corresponding to an input voltage value equal to ½ of an input dynamic range for A/D conversion. Accordingly, a local analog output voltage of the local digital-analog converter 17, which is supplied to an inversion input terminal − of the comparator 15, is set to the input voltage value equal to ½ of the input dynamic range. In this state, an analog input voltage supplied to a non-inversion input terminal + of the comparator 15 from the sample hold circuit 14 during a hold period, and the local analog output voltage of the inversion input terminal − are compared with each other. When the analog input voltage is higher than the local analog output voltage, the contents of the control register is changed to a digital value corresponding to an input voltage value equal to ¾ of the input dynamic range for A/D conversion. On the other hand, when the analog input voltage is lower than the local analog output voltage, the contents of the control register is changed to a digital value corresponding to an input voltage value equal to ¼ of the input dynamic range for A/D conversion. Now assume where the analog input voltage is higher than the local analog output voltage by way of example.

At a second step for A/D conversion of the successive approximation type analog-digital converter, an analog input voltage supplied from the sample hold circuit 14 to the non-inversion input terminal + of the comparator 15 during a hold period, and a local analog output voltage of the inversion input terminal −, corresponding to the input voltage value equal to ¾ of the input dynamic range for A/D conversion are compared with each other. When the analog input voltage is higher than the local analog output voltage, the contents of the control register is changed to a digital value corresponding to an input voltage value equal to ⅞ of the input dynamic range for A/D conversion. When the analog input voltage is lower than the local analog output voltage, the contents of the control register is changed to a digital value corresponding to an input voltage value equal to 8/5 of the input dynamic range for A/D conversion. Since the contents of the control register lying inside the controller 16 follows the voltage level of the analog input voltage by successive approximation in this manner, each of the multibit digital output signals D1 through D_{N} generated from the controller 16 follows the voltage amplitude level of the analog input voltage.

<<Digital Corrector>>

In a manner similar to FIG. 1, although not illustrated in FIG. 3, the digital corrector 18 included in the background digital correction type analog-digital converter shown in FIG. 3 includes a subtractor 19, a multiplier 110, a constant multiplier 111, an integrator 112, and a digital output generator 113. The operation of a digital correction by the digital corrector 18 included in the background digital correction type analog-digital converter shown in FIG. 3 is exactly similar to FIG. 1, and the description of its operation will therefore be omitted.

<<ΣΔ A/D Converter of Reference Analog-Digital Conversion Unit>>

The reference analog-digital conversion unit 10 of the background digital correction type analog-digital converter according to the first embodiment of the present invention shown in FIG. 3 includes cascade couplings between an impulse hold circuit 21, a ΣΔ analog-digital converter 22 and a Nyquist filter 23.

In order to reduce the circuit scale and power consumption of the A/D converter of the reference analog-digital conversion unit 10, the ΣΔ analog-digital converter 22 is adopted as the A/D converter of the reference analog-digital conversion unit 10. As a result, as compared with the case where the pipelined analog-digital converter or the successive approximation type A/D converter is adopted as the A/D converter of the reference analog-digital conversion unit 10, the adoption of the ΣΔ analog-digital converter 22 enables the circuit scale and power consumption of the reference analog-digital conversion unit 10 to be reduced drastically.

With the adoption of the ΣΔ analog-digital converter 22 in the reference analog-digital conversion unit 10, however, a reduction in a signal vs. quantization error ratio due to each quantization error diffused into a high frequency region by noise shaping of the ΣΔ analog-digital converter 22, and a reduction in effective resolution lead to problems as mentioned at the outset.

In order to solve the problems, the quantization error is sufficiently suppressed by a narrowband filter having a frequency band of 0 to 1/(2T). On the other hand, as a result, the Nyquist filter 23 becomes effective in which even though information on the frequency axis of each side lobe is suppressed, information about a conversion sample point can be maintained on the time base.

On the other hand, since the Nyquist filter 23 is premised on the supply of the pulse input signal for every constant symbol period T, the impulse hold circuit 21 is coupled to the input terminal of the ΣΔ analog-digital converter 22 in the background digital correction type analog-digital converter according to the first embodiment of the present invention shown in FIG. 3. The impulse hold circuit 21 samples a continuous-time analog input voltage supplied to the analog input terminal IN for every constant symbol period T to thereby generate an impulse signal and supplies the same to the input terminal of the ΣΔ analog-digital converter 22.

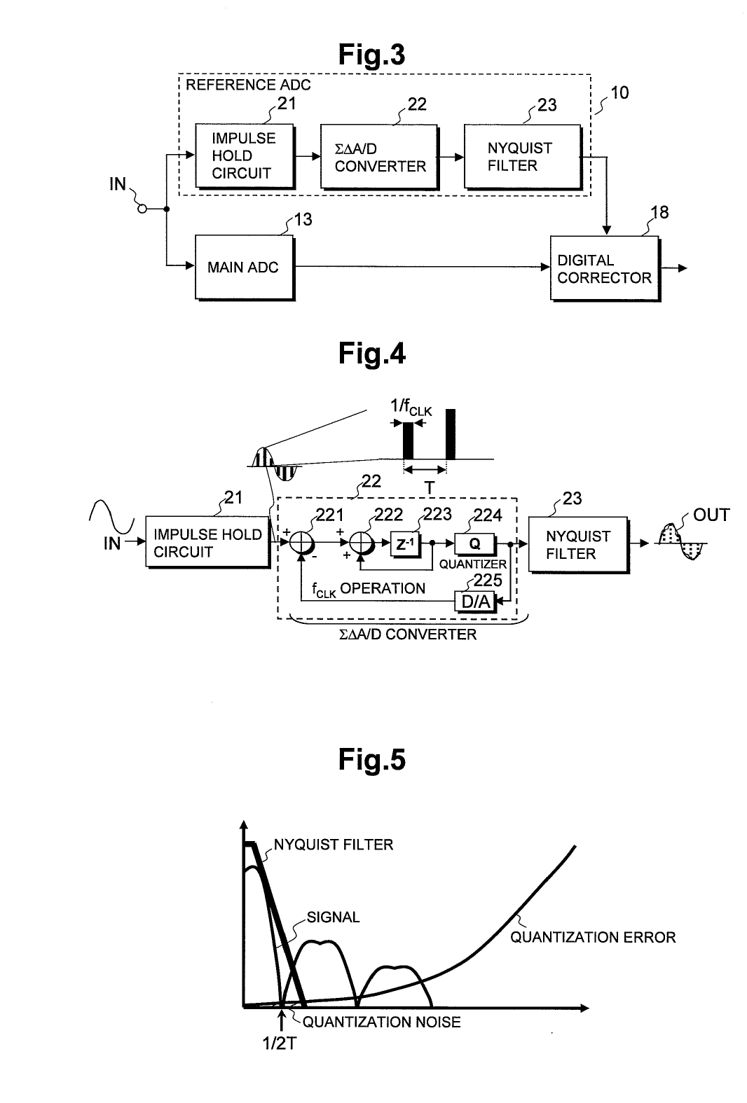

FIG. 4 is a diagram for further describing the operations of the impulse hold circuit 21, ΣΔ analog-digital converter 22, and Nyquist filter 23 included in the reference analog-digital conversion unit 10 of the background digital correction type analog-digital converter according to the first embodiment of the present invention shown in FIG. 3.

Although not shown in FIG. 4, an oversampling clock signal having a frequency f_{CLK} supplied to the ΣΔ analog-digital converter 22 is supplied even to the impulse hold circuit 21. Thus, the impulse hold circuit 21 samples a continuous-time analog input voltage supplied to the analog input terminal IN for every constant symbol period T to thereby generate an impulse signal and supplies the same to the input terminal of the ΣΔ analog-digital converter 22. A symbol period T corresponding to a sampling period of the impulse signal can be set to an integral multiple of a period f_{CLK}. A hold period (pulse width) of the impulse signal is set to the period 1/f_{CLK}. Incidentally, at this time, 1/T becomes a conversion rate effective as for the reference analog-digital conversion unit 10.

As shown in FIG. 4, the ΣΔ analog-digital converter 22 includes a subtractor 221, an adder 222, a delayer 223, a quantizer 224 and a D/A converter 225.

One input terminal of the subtractor 221 is supplied with an analog impulse signal generated from the impulse hold circuit 21. The other input terminal of the subtractor 22 is supplied with an analog delay negative feedback signal generated from the D/A converter 225. The subtractor 221 performs a differential operation (Δ) on the analog input signal. The adder 222 and the delayer 223 perform an analog integral operation (Σ) on an analog differential output signal of the subtractor 221. The 1-bit quantizer 224 converts an analog integral output signal of the adder 222 and the delayer 223 to a 1-bit digital signal. A pulse density of the 1-bit digital signal depends on the input voltage level of the ΣΔ analog-digital converter 22.

As shown in FIG. 4, the Nyquist filter 23 generates a digital filter output signal OUT in response to the 1-bit digital signal generated from the output terminal of the ΣΔ analog-digital converter 22 for every constant symbol period T.

FIG. 7 is a diagram showing an impulse response of the Nyquist filter 23 included in the reference analog-digital conversion unit 10 of the background digital correction type analog-digital converter according to the first embodiment of the present invention shown in FIG. 3.

As shown in FIG. 7, the waveform amplitude reaches a maximum value 1 with a symbol timing at a time zero of a symbol period T set to an integral multiple of the hold period (pulse width) 1/f_{CLK} of the impulse signal generated by the impulse hold circuit 21. The waveform amplitude becomes zero with another symbol timing equal to an integral multiple (−4T to −T and T to 4T) of the symbol period T. On the other hand, the 1-bit digital output signal of the ΣΔ analog-digital converter 22 is substantially the sum of the impulse-held analog signal being its input, and the noise-shaped high-frequency quantization error. As a result, the Nyquist filter 23 of FIG. 4 having such impulse response characteristics as shown in FIG. 7 does not cause intersymbol interference to the impulse-held analog signal substantially contained in the 1-bit digital output signal, i.e., it allows the held value to pass therethrough without a change in the value as it is.

On the other hand, the Nyquist filter 23 is capable of sufficiently suppressing the quantization error contained in the 1-bit digital output signal as a low-pass filter having a narrowband of 1/2T. As shown in FIG. 7, the roll-off factor α of the Nyquist filter 23 can be set to a value of 0≦α≦1. When α=0, the linking of the impulse response becomes maximum, whereas when α=1, the linking of the impulse response becomes minimum.

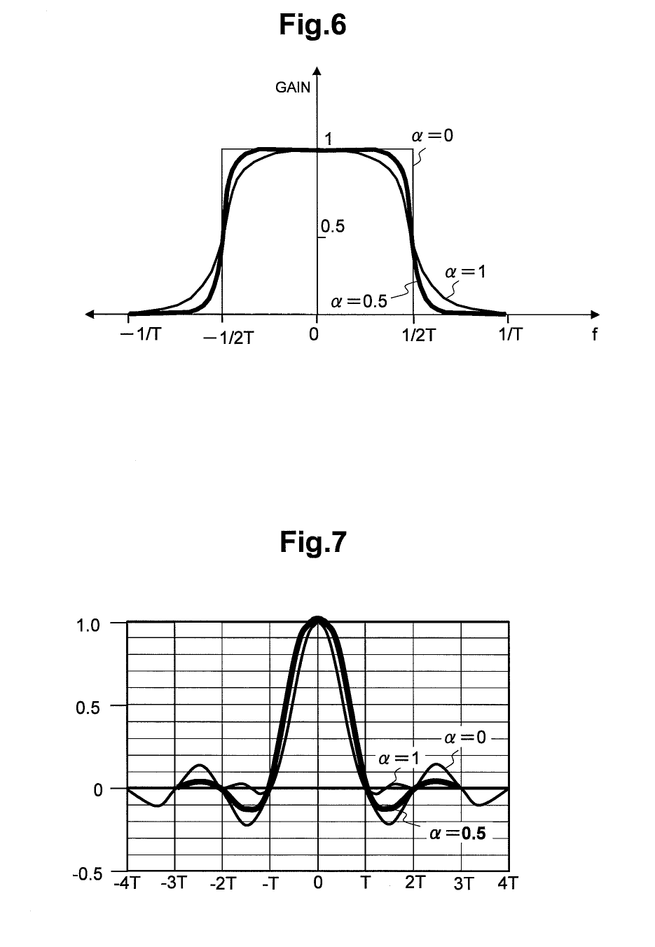

FIG. 6 is a diagram illustrating a frequency characteristic for band limiting of the Nyquist filter 23 included in the reference analog-digital conversion unit 10 of the background digital correction type analog-digital converter according to the first embodiment of the present invention shown in FIG. 3.

As shown in FIG. 6, the gain of the Nyquist filter 23 becomes a maximum value 1 at a zero frequency corresponding to a symbol timing at a time zero of a symbol period T. The gain of the Nyquist filter 23 becomes 0.5 equal to half of the maximum value at a frequency ±1/2T corresponding to twice the symbol period T. The gain of the Nyquist filter 23 becomes approximately zero at a frequency ±1/T corresponding to one time the symbol period T. Incidentally, as shown in FIG. 6, when α=0, the Nyquist filter serves as a brick wall filter in which the amplitude steeply changes at the characteristic frequency ±1/2T. When α=0.5 or α=1.0, the amplitude gently changes with the characteristic frequency as the boundary.

Incidentally, as will be explained in FIGS. 12 and 13 to be described later, the Nyquist filter 23 shown in FIGS. 3 and 4 can be achieved by an FIR digital filter. Incidentally, FIR is an abbreviation of Infinite Impulse Response. Further, as the value of the roll-off factor α of the Nyquist filter 23 increases, the number of coupling taps necessary for the FIR digital filter for achieving the Nyquist filter 23 can be reduced, thus making it possible to reduce the circuit scale and power consumption of the Nyquist filter 23. Since the narrow band is reached as the value of α becomes smaller, a quantization error can be more suppressed. The effect of reducing intersymbol interference of the Nyquist filter 23 is effective without α. Incidentally, the present invention is effective even other than the 1-bit quantizer used as the quantizer 224 of the ΣΔ analog-digital converter 22.

### Second Embodiment

### Configuration of Analog-Digital Converter According to Second Embodiment

FIG. 8 is a diagram showing a configuration of a background digital correction type analog-digital converter according to a second embodiment of the present invention, which is used as an analog-digital converter that enables high resolution and a high sample rate to be compatible.

The background digital correction type analog-digital converter according to the second embodiment of the present invention shown in FIG. 8 is different from the background digital correction type analog-digital converter according to the first embodiment of the present invention shown in FIG. 3 in that the impulse hold circuit 21 shown in FIG. 3 is replaced with a rectangular hold circuit 24 shown in FIG. 8, and an equivalent filter 25 is added between the output of a Nyquist filter 23 and the input of a digital corrector 18. The background digital correction type analog-digital converter according to the second embodiment of the present invention shown in FIG. 8 is identical in other configuration to that according to the first embodiment of the present invention shown in FIG. 3, and the description thereof will therefore be omitted.

FIG. 9 is a diagram for further describing the operations of the rectangular hold circuit 24, ΣΔ analog-digital converter 22, Nyquist filter 23 and equivalent filter 25 included in a reference analog-digital conversion unit 10 of the background digital correction type analog-digital converter according to the second embodiment of the present invention shown in FIG. 8.

Although not shown in FIG. 9, an oversampling clock signal having a frequency f_{CLK} supplied to the ΣΔ analog-digital converter 22 is supplied even to the rectangular hold circuit 24. Thus, the rectangular hold circuit 24 samples a continuous-time analog input voltage supplied to an analog input terminal IN for every constant symbol period T to thereby generate a rectangular hold signal and supplies the same to the input terminal of the ΣΔ analog-digital converter 22. A symbol period T corresponding to a sampling period of the rectangular hold signal can be set to an integral multiple of a period 1/f_{CLK}. A hold period (pulse width) of the rectangular hold signal is set to a symbol period T (integral multiple of period 1/f_{CLK}).

Since the ΣΔ analog-digital converter 22 of the reference analog-digital conversion unit 10 shown in FIG. 9 includes a subtractor 221, an adder 222, a delayer 223, a quantizer 224 and a D/A converter 225 in exactly the same manner as in FIG. 4, and is operated in exactly the same manner as in FIG. 4, the description of these will be omitted.

The Nyquist filter 23 of the reference analog-digital conversion unit 10 shown in FIG. 9 is configured and operated in exactly the same manner as the Nyquist filters 23 described in FIGS. 4, 5, 6 and 7, and the description thereof will therefore be omitted.

The equivalent filter 25 of the reference analog-digital conversion unit 10 shown in FIG. 9 is coupled between the output of the Nyquist filter 23 and the input of the digital corrector 18 as shown in FIG. 8 in order to generate exactly the same digital filter output signal OUT as the digital filter output signal OUT of the Nyquist filter 23 of FIG. 3 though the first stage circuit of the reference analog-digital conversion unit 10 shown in FIG. 3 is replaced from the impulse hold circuit 21 of FIG. 3 to the rectangular hold circuit 24 of FIG. 8. That is, the frequency characteristic of the equivalent filter 25 is selected to an inverse number of a frequency characteristic for impulse rectangular conversion, i.e., sin(πf/f_{CLK})/sin(πf_{T}). Accordingly, intersymbol interference is reduced with respect to the digital filter output signal OUT at the output terminal of the equivalent filter 25 as with the first embodiment.

Further, since a frequency characteristic corresponding to the product of the frequency characteristic of the Nyquist filter 23 shown in FIGS. 8 and 9 and the frequency characteristic of the equivalent filter 25 is a narrow band of about frequency band 0 to 1/2T after all, a quantization error can be sufficiently suppressed. As a result, the quantization errors noise-shaped and diffused into a high frequency region by the ΣΔ analog-digital converter 22 and the equivalent filter 25 are sufficiently suppressed by the digital filter output signal OUT of the equivalent filter 25, thus making it possible to solve degradation in the effective resolution of the reference analog-digital conversion unit 10 of the background digital correction type analog-digital converter. As will be explained in FIGS. 12 and 13 to be described later, each of the Nyquist filter 23 and the equivalent filter 25 shown in FIGS. 8 and 9 can be achieved by an FIR digital filter. Incidentally, the two filters may also be achieved by one FIR digital filter having the frequency characteristic of the product of the two.

### Third Embodiment

### Configuration of Analog-Digital Converter According to Third Embodiment

FIG. 10 is a diagram showing a configuration of a background digital correction type analog-digital converter according to a third embodiment of the present invention, which is used as an analog-digital converter capable of making high resolution and a high sample rate compatible.

The background digital correction type analog-digital converter according to the third embodiment of the present invention shown in FIG. 10 is different from the background digital correction type analog-digital converter according to the first embodiment of the present invention shown in FIG. 3 in that the impulse hold circuit 21 shown in FIG. 3 is replaced with an M-period hold circuit 26 shown in FIG. 10, and an equivalent filter 25 is added between the output of a Nyquist filter 23 and the input of a digital corrector 18. The background digital correction type analog-digital converter according to the second embodiment of the present invention shown in FIG. 10 is identical in other configuration to that according to the first embodiment of the present invention shown in FIG. 3, and the description thereof will therefore be omitted.

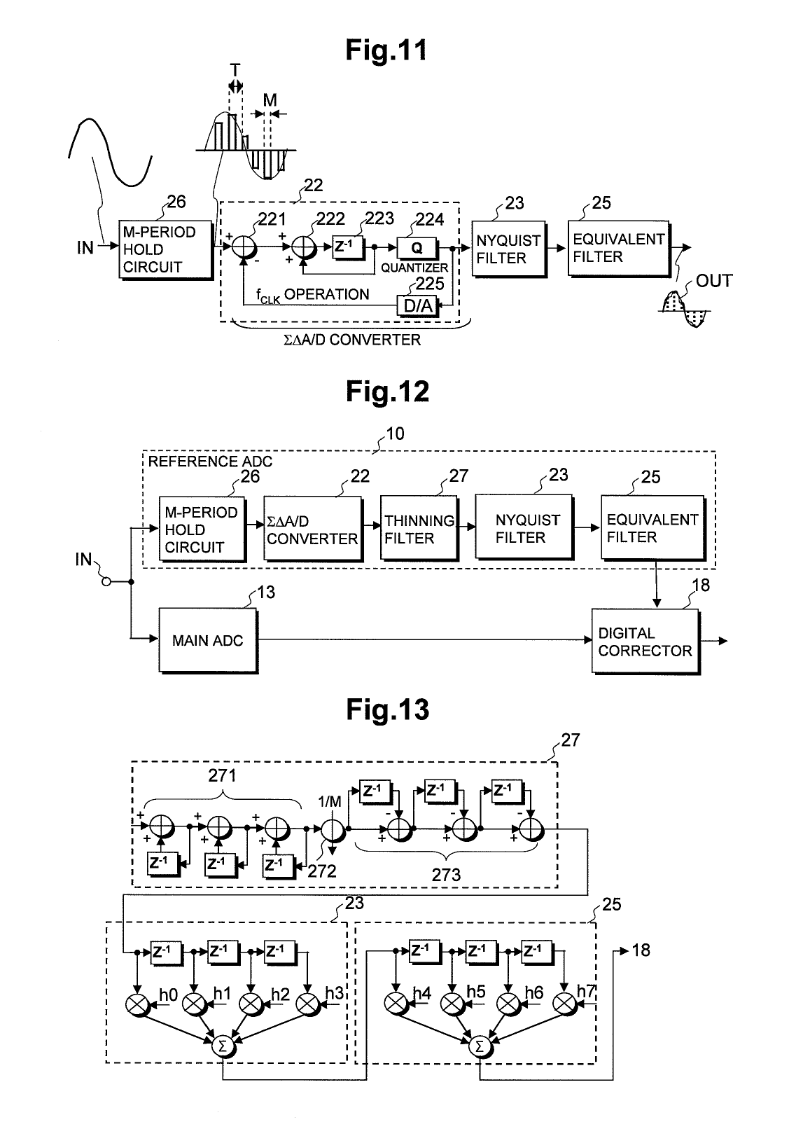

FIG. 11 is a diagram for further describing the operations of the M-period hold circuit 26, ΣΔ analog-digital converter 22, Nyquist filter 23 and equivalent filter 25 included in a reference analog-digital conversion unit 10 of the background digital correction type analog-digital converter according to the third embodiment of the present invention shown in FIG. 10.

Although not shown in FIG. 10, an oversampling clock signal having a frequency f_{CLK} supplied to the ΣΔ analog-digital converter 22 is supplied even to the M-period hold circuit 26. Thus, the M-period hold circuit 26 samples a continuous-time analog input voltage supplied to an analog input terminal IN for every constant symbol period T to thereby generate an M-period hold signal and supplies the same to the input terminal of the ΣΔ analog-digital converter 22. A symbol period T corresponding to a sampling period of the M-period hold signal can be set to an integral multiple of a period 1/f_{CLK}. A hold period (pulse width) of the M-period hold signal is set to M times the period 1/f_{CLK}. Incidentally, M is an odd or even integer.

Since the ΣΔ analog-digital converter 22 of the reference analog-digital conversion unit 10 shown in FIG. 11 includes a subtractor 221, an adder 222, a delayer 223, a quantizer 224 and a D/A converter 225 in exactly the same manner as in FIG. 4, and is operated in exactly the same manner as in FIG. 4, the description of these will be omitted.

The Nyquist filter 23 of the reference analog-digital conversion unit 10 shown in FIG. 11 is configured and operated in exactly the same manner as the Nyquist filters 23 described in FIGS. 4, 5, 6 and 7, and the description thereof will therefore be omitted.

The equivalent filter 25 of the reference analog-digital conversion unit 10 shown in FIG. 11 is coupled between the output of the Nyquist filter 23 and the input of the digital corrector 18 as shown in FIG. 10 in order to generate exactly the same digital filter output signal OUT as the digital filter output signal OUT of the Nyquist filter 23 of FIG. 3 though the first stage circuit of the reference analog-digital conversion unit 10 shown in FIG. 3 is replaced from the impulse hold circuit 21 of FIG. 3 to the M-period hold circuit 26 of FIG. 10. That is, the frequency characteristic of the equivalent filter 25 is selected to an inverse number of a frequency characteristic for impulse rectangular conversion, i.e., sin(πf/f_{CLK})/sin(πf_{T}). Accordingly, intersymbol interference is reduced with respect to the digital filter output signal OUT from the output terminal of the equivalent filter 25 as with the first embodiment.

Further, since a frequency characteristic corresponding to the product of the frequency characteristic of the Nyquist filter 23 shown in FIGS. 10 and 11 and the frequency characteristic of the equivalent filter 25 is a narrow band of about frequency band 0 to 1/2T after all, a quantization error can be sufficiently suppressed. As a result, the quantization error noise-shaped and diffused into a high frequency region by the ΣΔ analog-digital converter 22 and the equivalent filter 25 is sufficiently suppressed by the digital filter output signal OUT of the equivalent filter 25, thus making it possible to solve degradation in the effective resolution of the reference analog-digital conversion unit 10 of the background digital correction type analog-digital converter. As will be explained in FIGS. 12 and 13 to be described later, each of the Nyquist filter 23 and the equivalent filter 25 shown in FIGS. 10 and 11 can be achieved by an FIR digital filter. Incidentally, the two filters may also be achieved by one FIR digital filter having the frequency characteristic of the product of the two.

### Fourth Embodiment

### Configuration of Analog-Digital Converter According to Fourth Embodiment

FIG. 12 is a diagram showing a configuration of a background digital correction type analog-digital converter according to a fourth embodiment of the present invention, which is used as an analog-digital converter that enables high resolution and a high sample rate to be compatible.

The background digital correction type analog-digital converter according to the fourth embodiment of the present invention shown in FIG. 12 is different from the background digital correction type analog-digital converter according to the third embodiment of the present invention shown in FIG. 10 in that a thinning filter 27 is added between the output of a ΣΔ analog-digital converter 22 and the input of a Nyquist filter 23. The background digital correction type analog-digital converter according to the fourth embodiment of the present invention shown in FIG. 12 is identical in other configuration to that according to the third embodiment of the present invention shown in FIG. 10, and the description thereof will therefore be omitted.

In the reference analog-digital conversion unit 10 of the background digital correction type analog-digital converter shown in FIG. 12, the frequency of a signal band of the digital filter comprised of the Nyquist filter 23 and equivalent filter 25 is lower than the frequency f_{CLK} of an oversampling clock signal supplied to the ΣΔ analog-digital converter 22. As the ratio between the signal bands of the high frequency f_{CLK} of the oversampling clock signal and its low frequency becomes larger, the number of coupling taps necessary for an FIR filter for achieving the digital filter comprised of the Nyquist filter 23 and the equivalent filter 25 increases, thus resulting in increases in circuit scale and power consumption.

As described in the non-patent document 4 or the like, the thinning filter called decimation filter is coupled to the output of the ΣΔ analog-digital converter so that the conversion of frequency from the high frequency f_{CLK} of the oversampling clock signal to the lower frequency is performed.

Even in the reference analog-digital conversion unit 10 shown in FIG. 12, the thinning filter 27 similar to the decimation filter described in the non-patent document 4 or the like is coupled between the output of the ΣΔ analog-digital converter 22 and the input of the Nyquist filter 23. Thus, since the thinning filter 27 performs frequency conversion in accordance with a thinning signal process, the number of coupling taps necessary for the FIR filter for implementing the digital filter comprised of the Nyquist filter 23 and the equivalent filter 25 can be reduced in the reference analog-digital conversion unit 10 shown in FIG. 12, thereby making it possible to reduce the circuit scale and power consumption. Incidentally, the effects of the addition of the thinning filter 27 on the frequency characteristics can be cancelled out or compensated by appropriately changing the frequency characteristic of the equivalent filter 25.

FIG. 13 is a diagram showing a configuration of each of the thinning filter 27, Nyquist filter 23 and equivalent filter 25 included in the reference analog-digital conversion unit 10 shown in FIG. 12.

As shown in FIG. 13, the thinning filter 27 includes a feedback type integrator 27 comprised of a plurality of delayers and a plurality of adders, a down sampler 272 for thinning, and a feed-forward type differentiator 217 comprised of a plurality of delayers and a plurality of subtractors. The thinning filter 27 is called a CIC filter which executes a decimation process based on a downsampling process. Incidentally, CIC is an abbreviation of Cascaded Integrated Comb.

Further, as shown in FIG. 13, each of the Nyquist filter 23 and the equivalent filter 25 includes a plurality of delayers and a plurality of multipliers and adders and is hence comprised of an FIR filter capable of executing a sum-of-products operation.

### Fifth Embodiment

### Configuration of Analog-Digital Converter According to Fifth Embodiment

FIG. 14 is a diagram showing a configuration of a pipelined analog-digital converter usable as the main analog-digital conversion unit 13 of each of the background digital correction type analog-digital converters according to all of the first through fourth embodiments of the present invention.

As shown in FIG. 14, the background type analog-digital converter usable as the main analog-digital conversion unit 13 includes a plurality of unit circuits 30, 31, . . . 3N, and a delay control data output unit 3M.

As shown above FIG. 14, each of the unit circuits 30, 31, . . . 3N includes a sample hold circuit 311, an A/D converter 312, a D/A converter 313, a subtractor 314 and an amplifier 315. An analog input signal supplied to an input terminal 316 of each unit circuit is supplied to an input terminal of the sample hold circuit 311. A hold analog output signal at the output terminal of the sample hold circuit 311 is compared with a reference voltage Vref by the A/D converter 312 from which a digital output signal 317 is generated.

The hold analog output signal from the sample hold circuit 311 is supplied to one input terminal of the subtractor 314. On the other hand, the digital output signal 317 from the A/D converter 312 is converted to an analog output signal by the D/A converter 313. The analog output signal of the D/A converter 313 is supplied to the other input terminal of the subtractor 314. A difference signal corresponding to the output of the subtractor 314 is amplified by the amplifier 315 of which the gain is set to 2. A residual signal 318 generated from the output of the amplifier 315 is supplied to an input terminal 316 of a unit circuit of a subsequent stage.

Thus, an analog input voltage of an analog input terminal IN of the background digital correction type analog-digital converter is supplied to the input terminal 316 of the first-stage unit circuit 30. A digital output signal 317 of the first-stage unit circuit 30 is supplied to its corresponding first input terminal of the delay control data output unit 3M as a digital signal of MSB (Most Significant Bit). A residual signal 318 of the first-stage unit circuit 30 is supplied to its corresponding input terminal 316 of the second-stage unit circuit 31. A digital output signal 317 of the second-stage unit circuit 30 is supplied to its corresponding second terminal of the delay control data output unit 3M as a digital signal of a second bit. Subsequently, in like manner, a residual signal 318 of the N−1th-stage unit circuit 3(N−1) is supplied to its corresponding input terminal 316 of the Nth-stage unit circuit 3N. A digital output signal 317 of the Nth-stage unit circuit 3N is supplied to its corresponding Nth input terminal of the delay control data output unit 3M as a digital signal of the LSB (Least Significant Bit).

The delay control data output unit 3M adjusts differences between delay times of a plurality of input signals supplied from the first input terminal to the Nth input terminal to generate multibit digital output signals D₁ through D_{N} and supplies the same to the digital corrector 18.

While the invention made above by the present inventors has been described specifically on the basis of various embodiments, the present invention is not limited to the embodiments. It is needless to say that various changes can be made thereto within the scope not departing from the gist thereof.

For example, a search algorithm of the digital values of the multibit digital output signals D₁ through D_{N} of the control register lying inside the controller 16 in the successive approximation type A/D converter used as the main analog-digital conversion unit 13 of the background digital correction type analog-digital converter according to the first embodiment of the present invention shown in FIG. 3 is not limited to a binary search. It is needless to say that other search algorithms such as a non-binary search, etc. can be used.

Further, the thinning filter 27 provided between the output of the ΣΔ analog-digital converter 22 and the input of the Nyquist filter 23 in the fourth embodiment of the present invention described using FIG. 12 can be adopted in like manner even in the first embodiment of the present invention shown in FIG. 3, the second embodiment of the present invention shown in FIG. 8, and the third embodiment of the present invention shown in FIG. 10.

What is claimed is:

1. An analog-digital converter configured as a background digital correction type analog-digital converter, comprising:
a reference analog-digital conversion unit;
a main analog-digital conversion unit; and
a digital corrector,
wherein an input terminal of the reference analog-digital conversion unit and an input terminal of the main analog-digital conversion unit are coupled to an analog input terminal of the analog-digital converter to thereby allow the reference analog-digital conversion unit and the main analog-digital conversion unit to perform an analog-digital converting operation on substantially the same analog input voltage supplied to the analog input terminal,
wherein the main analog-digital conversion unit is capable of executing an analog-digital converting operation at a speed faster than that of the reference analog-digital conversion unit, whereas the reference analog-digital conversion unit is capable of executing an analog-digital converting operation with a resolution higher than that of the main analog-digital conversion unit,
wherein each of main digital output signals generated by the analog-digital converting operation of the main analog-digital conversion unit is capable of being supplied to one input terminal of the digital corrector, and a reference digital output signal generated by the analog-digital converting operation of the reference analog-digital conversion unit is capable of being supplied to the other input terminal of the digital corrector,
wherein the digital corrector is capable of outputting a correction-processing digital output signal generated in response to each of the main digital output signals and the reference digital output signal as a digital conversion output signal of the analog-digital converter, and
wherein the reference analog-digital conversion unit includes a ΣΔ analog-digital converter capable of responding to the analog input voltage supplied to the analog input terminal, and a Nyquist filter which is capable of responding to an output signal of the ΣΔ analog-digital converter and supplying the output signal to the other input terminal of the digital corrector as the reference digital output signal.

2. The analog-digital converter according to claim 1,
wherein the main analog-digital conversion unit comprises either a successive approximation type analog-digital converter or a pipelined analog-digital converter.

3. The analog-digital converter according to claim 2,
wherein the reference analog-digital conversion unit further comprises a signal hold circuit capable of generating a pulse signal by sampling the analog input voltage supplied to the analog input terminal for every predetermined symbol period and supplying the same to an input terminal of the ΣΔ analog-digital converter.

4. The analog-digital converter according to claim 3,
wherein the Nyquist filter has an impulse response set in such a manner that an amplitude waveform becomes a predetermined magnitude with a symbol timing at a zero time of the predetermined symbol period, and
wherein the amplitude waveform becomes substantially zero with another symbol timing equal to an integral multiple of the predetermined symbol period.

5. The analog-digital converter according to claim 4,
wherein the signal hold circuit comprises an impulse hold circuit which samples the analog input voltage for every predetermined symbol period to thereby generate an impulse signal having a pulse width shorter than the predetermined symbol period.

6. The analog-digital converter according to claim 4,
wherein the signal hold circuit comprises a rectangular hold circuit which samples the analog input voltage for every predetermined symbol period to thereby generate a rectangular pulse signal having a pulse width substantially equal to the predetermined symbol period.

7. The analog-digital converter according to claim 6,
wherein the reference analog-digital conversion unit further comprises an equivalent filter coupled between an output terminal of the Nyquist filter and the other input terminal of the digital corrector.

8. The analog-digital converter according to claim 4,
wherein the signal hold circuit comprises a period hold circuit which samples the analog input voltage for every predetermined symbol period to thereby generate a hold pulse signal having a hold period shorter than the predetermined symbol period.

9. The analog-digital converter according to claim 8,
wherein the reference analog-digital conversion unit further comprises an equivalent filter coupled between an output terminal of the Nyquist filter and the other input terminal of the digital corrector.

10. The analog-digital converter according to claims 1,
wherein the reference analog-digital conversion unit further comprises a thinning filter coupled between an output terminal of the ΣΔ analog-digital converter and an input terminal of the Nyquist filter.

11. An operating method of an analog-digital converter configured as a background digital correction type analog-digital converter comprising:
a reference analog-digital conversion unit;
a main analog-digital conversion unit; and
a digital corrector,
wherein an input terminal of the reference analog-digital conversion unit and an input terminal of the main analog-digital conversion unit are coupled to an analog input terminal of the analog-digital converter to thereby allow the reference analog-digital conversion unit and the main analog-digital conversion unit to perform an analog-digital converting operation on substantially the same analog input voltage supplied to the analog input terminal,
wherein the main analog-digital conversion unit is capable of executing an analog-digital converting operation at a speed faster than that of the reference analog-digital conversion unit, whereas the reference analog-digital conversion unit is capable of executing an analog-digital converting operation with a resolution higher than that of the main analog-digital conversion unit,
wherein each of main digital output signals generated by the analog-digital converting operation of the main analog-digital conversion unit is capable of being supplied to one input terminal of the digital corrector, and a reference digital output signal generated by the analog-digital converting operation of the reference analog-digital conversion unit is capable of being supplied to the other input terminal of the digital corrector,
wherein the digital corrector is capable of outputting a correction-processing digital output signal generated in response to each of the main digital output signals and the reference digital output signal as a digital conversion output signal of the analog-digital converter,
wherein the reference analog-digital conversion unit comprises a ΣΔ analog-digital converter capable of responding to the analog input voltage supplied to the analog input terminal, and a Nyquist filter which is capable of responding to an output signal of the ΣΔ analog-digital converter and supplying the output signal to the other input terminal of the digital corrector as the reference digital output signal, and
wherein the Nyquist filter is operated so as to suppress a quantization error in high frequency of the ΣΔ analog-digital converter.

12. The operating method of the analog-digital converter according to claim 11,
wherein the main analog-digital conversion unit comprises either a successive approximation type analog-digital converter or a pipelined analog-digital converter.

13. The operating method of the analog-digital converter according to claim 12,
wherein the reference analog-digital conversion unit further comprises a signal hold circuit capable of generating a pulse signal by sampling the analog input voltage supplied to the analog input terminal for every predetermined symbol period and supplying the same to an input terminal of the ΣΔ analog-digital converter.

14. The operating method of the analog-digital converter according to claim 13,
wherein the Nyquist filter has an impulse response set in such a manner that an amplitude waveform becomes a predetermined magnitude with a symbol timing at a zero time of the predetermined symbol period, and
wherein the amplitude waveform becomes substantially zero with another symbol timing equal to an integral multiple of the predetermined symbol period.

15. The operating method of the analog-digital converter according to claim 14,
wherein the signal hold circuit comprises an impulse hold circuit which samples the analog input voltage for every predetermined symbol period to thereby generate an impulse signal having a pulse width shorter than the predetermined symbol period

16. The operating method of the analog-digital converter according to claim 14,
wherein the signal hold circuit comprises a rectangular hold circuit which samples the analog input voltage for every predetermined symbol period to thereby generate a rectangular pulse signal having a pulse width substantially equal to the predetermined symbol period.

17. The operating method of the analog-digital converter according to claim 16,
wherein the reference analog-digital conversion unit further comprises an equivalent filter coupled between an output terminal of the Nyquist filter and the other input terminal of the digital corrector.

18. The operating method of the analog-digital converter according to claim 14,
wherein the signal hold circuit comprises a period hold circuit which samples the analog input voltage for every predetermined symbol period to thereby generate a hold pulse signal having a hold period shorter than the predetermined symbol period.

19. The operating method of the analog-digital converter according to claim 18,
wherein the reference analog-digital conversion unit further comprises an equivalent filter coupled between an output terminal of the Nyquist filter and the other input terminal of the digital corrector.

20. The operating method of the analog-digital converter according to claims 11,
wherein the reference analog-digital conversion unit further comprises a thinning filter coupled between an output terminal of the ΣΔ analog-digital converter and an input terminal of the Nyquist filter.
